(19) United States
(12) Patent Application Publication
(10) Pub. No.: US 2010/0276275 A1
(43) Pub. Date: Nov. 4, 2010

(54) METHOD OF GENERATING FINE METAL PARTICLES, METHOD OF MANUFACTURING METAL-CONTAINING PASTE, AND METHOD OF FORMING THIN METAL FILM INTERCONNECTION

(75) Inventors: Koichi SASAKI, Sapporo-shi (JP); Masayoshi Ikeda, Hachioji-shi (JP); Yasumi Sago, Tachikawa-shi (JP)

Correspondence Address: FITZPATRICK CELLA HARPER & SCINTO, 1290 Avenue of the Americas, NEW YORK, NY, 10104-3800, US

(73) Assignees: Canon Anelva Corporation, Kawasaki-shi (JP); National University Corporation Nagoya University, Nagoya-shi (JP)

(21) Appl. No.: 12/836,906

(22) Filed: Jul. 15, 2010

Related U.S. Application Data
(63) Continuation of application No. PCT/JP2009/050834, filed on Jan. 21, 2009.

(30) Foreign Application Priority Data
Jan. 22, 2008 (JP) 2008-011801

(51) Int. Cl. C23C 14/34; C23C 14/35

(52) U.S. Cl. 204/192.15

(57) ABSTRACT

There is provided a method or the like which safely generates fine metal particles at a low cost without using a chlorine gas. Fine copper particles (101a, 101b) are generated by placing a copper target (2) in a chamber (6) of a sputtering apparatus, generating a plasma (100) in the chamber (6) while setting the pressure in the chamber (6) at 13 Pa or more, and sputtering the copper target (2).

### TECHNICAL FIELD

The present invention relates to a method of generating metal particles, a method of manufacturing a metal-containing paste, and a method of forming a thin metal film interconnection.

### BACKGROUND ART

Recently, fine metal particles have been used in various fields, and demands have arisen for the manufacture of fine particles with small particle diameters. For example, a conductive paste is used as leads for many electronic devices. Mainly copper particles are dispersed in a conductive paste, and a lead having an arbitrary shape can be manufactured by evaporating the vaporized constituents of the paste. Recently, with further reductions in the size of electronic components, it is required to reduce the thickness of conductive paste films. For this purpose, it is required to reduce the particle diameter of copper particles in a conductive paste.

Conventionally, as a method of generating fine metal particles, a method like that disclosed in patent reference 1 is known. According to the method disclosed in patent reference 1, a copper component/chlorine precursor is generated by using chlorine and a copper member, and a film of the generated precursor is formed on a substrate. Thereafter, ultrafine copper particles are formed on the substrate by irradiating the precursor with atomic hydrogen from a reducing gas containing hydrogen.

Patent reference 1: Japanese Patent Laid-Open No. 2001-335959

### DISCLOSURE OF INVENTION

### Problems that the Invention is to Solve

The above conventional technique requires use of highly corrosive and toxic chlorine gas to perform a method of forming fine metal particles. On the other hand, metal components are generally used for members which form a chamber to provide adequate strength. When chlorine gas is to be used, however, there is a risk of causing corrosion of the product itself, or metal components of the chamber that may lead to leakage of the gas, unless apparatus management is sufficiently performed by frequently performing apparatus maintenance, temperature management, an apparatus sequence, and the like. However, enhancing apparatus maintenance, temperature management, an apparatus sequence, and the like will cause an increase in the cost of fine metal particles.

It is, therefore, an object of the present invention to provide a method or the like which safely generates fine metal particles at a low cost.

### Means of Solving the Problems

In order to achieve the above object, a method of generating fine metal particles according to the present invention is characterized by a step of placing a target made of a metal material in a chamber of a sputtering apparatus, and a step of generating fine metal particles by generating plasma in the chamber and sputtering the target while a pressure in the chamber is set at not less than 13 Pa.

### EFFECTS OF THE INVENTION

According to the present invention, it is possible to safely generate fine metal particles at a low cost. The present invention can also manufacture various kinds of fine metal particles.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a schematic view showing a magnetron sputtering apparatus used for a method of generating fine metal particles according to the first embodiment of the present invention; and

FIG. 2 is a schematic view showing a magnetron sputtering apparatus used for a method of generating fine metal particles according to the second embodiment of the present invention.

### BEST MODE FOR CARRYING OUT THE INVENTION

The embodiments of the present invention will be described in detail below. The constituent elements described in these embodiments are merely examples. The technical scope of the present invention is determined by the appended claims and is not limited to the following individual embodiments.

In a method of generating fine metal particles according to an embodiment of the present invention, first of all, for example, a target containing copper (e.g., copper, copper-nickel, copper-cobalt, copper-silicon, or copper-carbon) or a target containing aluminum, magnesium, titanium, or the like is placed in the chamber of a sputtering apparatus (preferably a magnetron sputtering apparatus). Plasma is then generated while the pressure in the chamber is set at 13 Pa or more, preferably about 26 Pa, to generate fine metal particles uniformly distributed in a vapor phase, thereby generating fine metal particles. In this case, it is preferable to introduce a discharge gas (e.g., a rare gas such as Ar gas) into the chamber.

In addition, it is possible to manufacture an electrically anisotropic conductive paste by generating fine metal particles using the above method of generating fine metal particles and making a paste material (an epoxy-based adhesive resin, phenol-based adhesive resin, or the like) containing the fine metal particles.

In addition, fine metal particles can be used as a powder raw material in powder metallurgy. This makes it possible to manufacture processed goods demanding high accuracy and fine products even by using metals which are difficult to process by using a forging method, casting method, and the like.

It is also possible to form thin metal film interconnections on a substrate by loading a semiconductor substrate such as a silicon wafer or a glass substrate into the chamber of the sputtering apparatus and depositing the fine metal particles generated in the above manner on the substrate. More specifically, it is possible to form thin metal film interconnections by forming a thin metal film by depositing, on the substrate, the fine metal particles generated by the above method of generating fine metal particles, and then patterning the thin metal film using a general photolithography technique.

According to this embodiment, the use of an inert gas (helium, argon gas, krypton gas, nitrogen gas, or the like) as a process gas can suppress the corrosion of the chamber components of the sputtering apparatus due to a corrosive gas such as chlorine. This embodiment can therefore omit apparatus maintenance operation, temperature management operation, and apparatus sequence management operation as countermeasures against corrosion. It is therefore possible to safely manufacture fine metal particles, a paste containing the fine metal particles, and thin metal film interconnections at a low cost.

The embodiments of the present invention will be described below.

### Embodiments

### First Embodiment

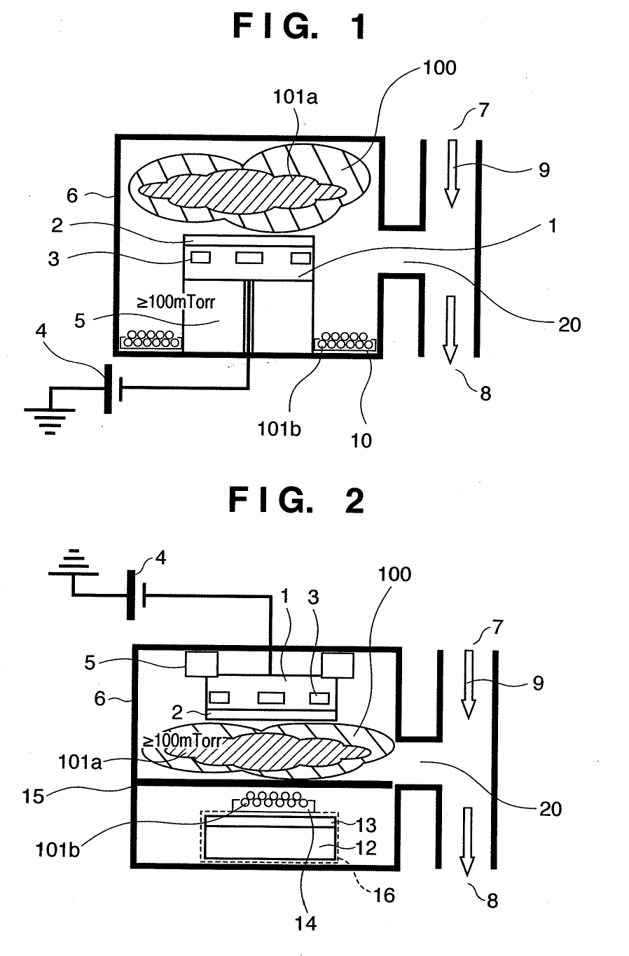

FIG. 1 is a schematic view showing a magnetron sputtering apparatus used for a method of generating fine metal particles according to the first embodiment of the present invention. This embodiment will exemplify a case in which fine copper particles are generated by using a copper target as a target.

The basic arrangement of a magnetron sputtering apparatus used for a method of generating fine metal particles according to this embodiment will be described first. This magnetron sputtering apparatus includes a chamber 6, a target electrode 1 placed on the lower surface side in the chamber 6 through an insulating component 5, a DC power supply 4 connected to the target electrode 1, and a recovery tray 10 placed on the bottom surface in the chamber 6. The chamber 6 is provided with a gas inlet 7 through which a discharge gas is introduced and a gas outlet 8 through which an exhaust gas is discharged from the chamber 6. The gas inlet 7 and the gas outlet 8 communicate with each other and are connected to the chamber 6 through a connection path 20. With this arrangement, the pressure in the chamber 6 is determined by only the diffusion of a gas.

The cathode side of the DC power supply 4 is connected to the target electrode 1, and the anode side is grounded. The target electrode 1 is placed such that the surface to be sputtered faces upward. A copper target 2 is placed on the surface to be sputtered. The target electrode 1 is provided with a cathode magnet 3 which generates a magnetic flux loop parallel to the surface to be sputtered such that it closes. This magnetic flux loop is generated to trap electrons on the surface of the copper target 2 when plasma 100 is generated in the chamber 6. It suffices to generate a single or a plurality of magnetic flux loops.

The operation of the above magnetron sputtering apparatus will be described next.

First of all, to prepare for the generation of fine copper particles, the chamber 6 is evacuated by a vacuum pump (not shown) connected to the gas outlet 8 until the base pressure in the chamber 6 becomes 1E-5 Pa or less. The pressure value in the chamber 6 without introducing a gas is checked by using a pressure gauge (not shown) (e.g., a full range gauge or crystal ion gauge). Note that the evacuation time can be shortened and the interior of the chamber 6 can be cleaned by heating the vacuum components in the chamber 6 using a heating mechanism (not shown) so as to facilitate the exhaustion of moisture and vaporized impurities on the components in the chamber 6. The heating mechanism stops heating the components when the base pressure in the chamber 6 becomes 1E-5 Pa or less. With the above operation, the preparation for the generation of fine copper particles is complete.

The generation of fine copper particles will be described next.

First of all, a rare gas such as Ar (argon) gas 9, which is an inert gas, is introduced as a discharge gas through the gas inlet 7. At this time, the pressure in the chamber 6 is measured by a pressure gauge (not shown) (e.g., a diaphragm gauge). To set the pressure in the chamber 6 to a desired pressure, e.g., 26 Pa, an exhaust conductance is adjusted by a variable orifice (not shown) placed between the gas outlet 8 and the exhaust pump (not shown). When the pressure reaches the desired pressure, the DC power supply 4 is turned on to supply desired power, e.g., 0.5 W/cm², to the target electrode 1 to generate the plasma 100 in the chamber 6. Copper atoms emitted from the copper target 2 into the plasma 100 bond with each other in a vapor phase and fine copper particles 101a start to drift in the plasma 100 a given time after the generation of the plasma 100.

In order to grow the fine copper particles 101a in a vapor phase, it is important to grow copper atoms into the fine copper particles 101a while eliminating the kinetic energy of the copper atoms in the plasma 100 as much as possible and confining them in the vapor phase.

The first point for this operation is to increase the frequency of collision between copper atoms or the fine copper particles 101a and a gas while maintaining the pressure in the chamber 6 at 13 Pa or more, preferably about 26 Pa. The upper limit of the pressure in the chamber 6 is preferably about 26 Pa.

The second point is to set the distance from the target electrode 1 to the inner wall surface of the chamber 6 to, for example, 40 mm or more, preferably 100 mm or more. This can sufficiently secure a space in the chamber 6 in which copper atoms driven out of the copper target 2 collide with the gas to lose energy.

In addition, to grow the fine copper particles 101a in the vapor phase, it is important to form an environment which does not hinder the fine copper particles 101a from drifting. For this purpose, in order to prevent the formation of a gas flow in the chamber 6, it is preferable to perform pressure control in the chamber 6 mainly based on gas diffusion by making the gas inlet 7 communicate with the gas outlet 8 and connecting them to the chamber 6 through the connection path 20, as described above.

After the plasma 100 is generated and an electric discharge is maintained for a predetermined period of time, the DC power supply 4 is turned off to finish the generation of the plasma 100. When the DC power supply 4 is turned off, the fine copper particles 101a drifting in the plasma 100 diffuse outward, in all directions, from the region where the plasma existed. The fine copper particles 101a which have diffused in all directions collide with the side and upper walls of the chamber 6 to bounce off the walls, are electrostatically attracted to the wall surface of the chamber 6, and lose their velocity in the space to drop to the bottom surface of the chamber 6. Some of the fine copper particles 101a enter the recovery tray 10 as fine metal particle recovery members placed on the bottom surface of the chamber 6, and are accumulated in the recovery tray 10. Copper particles accumulated in the recovery tray 10 will be referred to as “fine copper particles 101b” hereinafter. The fine copper particles 101b are generated in large quantities by repeatedly turning on/off the DC power supply 4 to repeat the generation of the fine copper particles 101a in the plasma 100 and the diffusion of the fine copper particles 101a in all directions in a state in which the generation of the plasma 100 is finished. With this operation, the many fine copper particles 101b are accumulated in the recovery tray 10.

Lastly, introducing an inert gas into the chamber 6 and opening the chamber 6 can recover the fine copper particles 101b accumulated in the recovery tray 10.

As described above, the method of generating fine metal particles according to this embodiment can generate fine copper particles without using chlorine gas. Therefore, there is no possibility that the constituent members of the sputtering apparatus will be corroded by chlorine gas. This can save the trouble required for management of the sputtering apparatus. In addition, there is no chance that a chlorine gas will leak from the chamber of the sputtering apparatus. It is therefore possible to safely generate fine copper particles at a low cost.

In addition, according to this embodiment, it is possible to generate the fine copper particles 101b having a uniform diameter distribution. More specifically, the diameters of the fine copper particles 101b, of all the fine copper particles 101b generated in this embodiment, which has 80 wt % or more are distributed in the range of 80 nm to 150 nm. As described above, according to this embodiment, fine copper particles exhibiting excellent diameter uniformity can be generated.

### Second Embodiment

FIG. 2 is a schematic view showing a magnetron sputtering apparatus used for a method of generating fine metal particles according to the second embodiment of the present invention. This embodiment will also exemplify a case in which fine copper particles are generated by using a copper target.

The basic arrangement of the magnetron sputtering apparatus used for the method of generating fine metal particles according to this embodiment will be described first. This magnetron sputtering apparatus includes a chamber 6, a target electrode 1 placed on the upper surface side in the chamber 6 through an insulating component 5, and a DC power supply 4 connected to the target electrode 1. In addition, a recovery substrate 14 to recover the fine copper particles generated in the chamber 6 and a substrate holder 16 to support the substrate are arranged on the bottom surface side in the chamber 6. The substrate holder 16 includes a holder 12 placed on the bottom surface of the chamber 6 and a stage 13 placed on the holder 12. The recovery substrate 14 is placed on the stage 13.

The chamber 6 is provided with a gas inlet 7 through which a discharge gas is introduced and a gas outlet 8 through which an exhaust gas is discharged from the chamber 6. The gas inlet 7 and the gas outlet 8 communicate with each other and are connected to the chamber 6 through a connection path 20. With this arrangement, the pressure in the chamber 6 is determined by only the diffusion of a gas.

The cathode side of the DC power supply 4 is connected to the target electrode 1, and the anode side is grounded. The target electrode 1 is placed such that the surface to be sputtered faces downward. The surface to be sputtered of the target electrode 1 faces the recovery substrate 14. A copper target 2 is attached to the surface to be sputtered. The target electrode 1 is provided with a cathode magnet 3 which generates a magnetic flux loop parallel to the surface to be sputtered such that it closes. This magnetic flux loop is generated to trap electrons on the surface of the copper target 2 when plasma 100 is generated in the chamber 6. It suffices to generate a single or a plurality of magnetic flux loops.

The magnetron sputtering apparatus according to this embodiment also includes a shutter mechanism 15 between the target electrode 1 and the substrate holder 16 in the chamber 6. The shutter mechanism 15 is configured to perform opening/closing operation. While the shutter mechanism 15 is closed, the first and second spaces in the chamber 6 in which the target electrode 1 and the substrate holder 16 are respectively placed are shut off from each other. While the shutter mechanism 15 is open, these spaces communicate with each other. In this manner, the shutter mechanism 15 partitions the inside of the chamber 6 into the first and second spaces and switches between the state in which the first and second spaces communicate with each other and the state in which the first and second spaces are shut off from each other. In this embodiment, the distance between the target electrode 1 and the shutter mechanism 15 is 40 mm or more, preferably 100 mm or more.

The operation of the magnetron sputtering apparatus used in the second embodiment will be described.

The process of generating fine copper particles 101a in a vapor phase in this embodiment is the same as that in the first embodiment. The description of the second embodiment will therefore focus on differences from the first embodiment.

The magnetron sputtering apparatus in this embodiment differs from that in the first embodiment in that the recovery substrate 14 faces the target electrode 1. In this embodiment as well, while the shutter mechanism 15 is open, the DC power supply 4 is turned on to generate the plasma 100 in the chamber 6 and generate the fine copper particles 101a in the plasma. Thereafter, the DC power supply 4 is turned off to accumulate fine copper particles 101b on the recovery substrate 14. However, since the surface to be sputtered of the target electrode 1 faces the recovery substrate 14, the plasma 100 generated in the chamber 6 reaches the recovery substrate 14 while the shutter mechanism 15 is open. If, therefore, the DC power supply 4 is repeatedly turned on and off to recover a large quantity of fine copper particles 101b as in the first embodiment, the fine copper particles 101b recovered on the recovery substrate 14 are repeatedly exposed to the plasma 100 which is repeatedly generated and eliminated. In this case, the fine copper particles 101b recovered on the recovery substrate 14 may bond with each other due to the influence of the plasma 100.

In this embodiment, therefore, while the fine copper particles 101a are generated in the plasma 100, the shutter mechanism 15 is closed to shut off the space in which the target electrode 1 is placed from the space in which the substrate holder 16 is placed. The shutter mechanism 15 is then opened immediately before the DC power supply 4 is turned off, and the fine copper particles 101b are accumulated on the recovery substrate 14 while the DC power supply 4 is OFF. When the DC power supply 4 is to be turned on again to generate the fine copper particles 101a, the shutter mechanism 15 is closed to shut off the above two spaces from each other immediately before the DC power supply 4 is turned on, thereby preventing the fine copper particles 101b on the recovery substrate 14 from bonding with each other due to the plasma 100.

Note that adding a mechanism to transfer the recovery substrate 14 to the magnetron sputtering apparatus shown in FIG. 2 in a vacuum makes it possible to recover the fine copper particles 101b without opening the chamber 6 to the atmosphere.

The above first and second embodiments have exemplified the case in which fine copper particles are generated. However, changing the material for a target from copper to another metal can generate fine particles of another metal. Each embodiment described above uses the magnetron sputtering apparatus having the DC power supply 4 connected to the target electrode 1. Even if, however, an AC power supply is connected to the target electrode 1, instead of the DC power supply 4, to apply AC power to the target electrode 1, it is possible to obtain similar functions and effects. Alternatively, it is possible to obtain similar functions and effects by connecting the DC power supply 4 and an AC power supply to the target electrode 1 and applying DC power and AC power to the target electrode 1 in a superimposed manner.

### Third Embodiment

The fine copper particles generated in the first and second embodiments described above were dispersed and contained in a phenol-based adhesive resin to manufacture an electrically anisotropic paste. When this electrically anisotropic paste was placed between the lead terminal portion of a liquid crystal panel and the lead terminal of a TAB film to bond and fix them, a connection structure with excellent electric conductivity and adhesiveness could be obtained.

### Fourth Embodiment

A silicon wafer substrate was placed at a position where the fine copper particles 101b in the chamber 6 in the first or second embodiment were deposited, and the fine copper particles 101b were deposited on the substrate. This made it possible to form, on a silicon wafer substrate, a thin copper film having lower resistance than a general thin copper film.

Patterning the thin metal film into a desired shape by using a general photolithography technique made it possible to form thin metal film interconnections on a silicon wafer substrate.

Although the preferred embodiments of the present invention have been described with reference to the accompanying drawings, the present invention is not limited to the embodiments and can be variously modified within the technical scope defined by the appended claims.

This application claims the benefit of Japanese Patent Application No. 2008-11801, filed Jan. 22, 2008, which is hereby incorporated by reference herein in its entirety.

1. A method of generating fine metal particles, comprising steps of:
placing a target made of a metal material in a chamber of a sputtering apparatus, and
generating fine metal particles by generating a plasma in the chamber while a pressure in the chamber is set at not less than 13 Pa and sputtering the target,
wherein a gas inlet through which a discharge gas is introduced into the chamber and a gas outlet through which a discharge gas is discharged from the chamber are connected to the chamber, and
the gas inlet and the gas outlet communicate with each other, and the gas inlet and the gas outlet are connected to the chamber through a connection path.

2. The method of generating fine metal particles according to claim 1, wherein a magnetron sputtering apparatus is used as the sputtering apparatus.

3. The method of generating fine metal particles according to claim 1, wherein a discharge gas is introduced into the chamber.

4. (canceled)

5. (canceled)

6. The method of generating fine metal particles according to claim 1, wherein the target is placed in the chamber at a distance of not less than 40 mm from an inner wall surface of the chamber.

7. The method of generating fine metal particles according claim 1, wherein fine metal particle recovery member on which the fine metal particles are deposited to be recovered is placed in the chamber.

8. The method of generating fine metal particles according to claim 7, wherein the fine metal particle recovery member is placed on a bottom surface of the chamber.

9. The method of generating fine metal particles according to claim 7, wherein the fine metal particle recovery member is placed at a position which is below the target and faces the target.

10. The method of generating fine metal particles according to claim 8, wherein a shutter mechanism which partitions an inside of the chamber into a first space in which the target is placed and a second space in which the fine metal particle recovery member is placed and switches between a state in which the first space communicates with the second space and a state in which the first space and the second space are shut off from each other is placed in the chamber.

11. The method of generating fine metal particles according to claim 10, wherein a distance between the target and the shutter mechanism is not less than 40 mm.

12. The method of generating fine metal particles according to claim 1, wherein a target made of one of copper and a copper alloy is used as a target.

13. A method of manufacturing a metal-containing paste, comprising a step of making a paste material contain fine metal particles generated by a method of generating fine metal particles defined in claim 1.

14. A method of forming a thin metal film interconnection, comprising steps of:
forming a thin metal film by depositing fine metal particles generated by a method of generating fine metal particles defined in claim 1 on a substrate placed in the chamber; and
forming an interconnection by patterning the thin metal film.
